(19) United States
(12) Patent Application Publication
(10) Pub. No.: US 2011/0074037 A1
(43) Pub. Date: Mar. 31, 2011

(54) SEMICONDUCTOR DEVICE

(75) Inventors: Hidehiro TAKESHIMA, Tokyo (JP); Susumu INAKAWA, Tokyo (JP)

(73) Assignee: Elpida Memory, Inc.

(21) Appl. No.: 12/888,625

(22) Filed: Sep. 23, 2010

(30) Foreign Application Priority Data
Sep. 29, 2009 (JP) 2009-224322

(51) Int. Cl. H01L 23/48

(52) U.S. Cl. 257/773; 257/E23.01; 257/787

(57) ABSTRACT

A device has a semiconductor chip, a wiring board, a support which supports the semiconductor chip on the wiring board and forms a gap between the semiconductor chip and the wiring board, and a sealing resin injected into the gap and covering the semiconductor chip.

This application is based upon and claims the benefit of priority from Japanese patent application No. 2009-224322, filed on Sep. 29, 2009, the disclosure of which is incorporated herein in its entirety by reference.

### BACKGROUND OF THE INVENTION

This invention relates to a semiconductor device and, in particular, to a semiconductor device in which a semiconductor chip is mounted on a wiring board and sealed with a resin.

CSP (Chip Size Package) or other types of semiconductor devices typically have a semiconductor chip mounted on a wiring board and sealed with resin. This type of semiconductor devices is susceptible to such a problem that warpage is caused by a difference in coefficient of thermal expansion between semiconductor chip and wiring board.

In order to solve such a problem, a related semiconductor device is designed to have a contact area between semiconductor chip and wiring board smaller than the area of the semiconductor chip, so that a first region with an adhesive and a second region with a sealing resin surrounding the first region are formed between the semiconductor chip and the wiring board. This type of semiconductor device is disclosed, for example, in Japanese Laid-Open Patent Publication No. 2005-142452 (Patent Document 1).

There are also known semiconductor devices employing a configuration similar to that described above for the purposes of reliability enhancement and size reduction. This type of semiconductor device is disclosed, for example, in Japanese Laid-Open Patent Publication No. 2006-128455 (Patent Document 2).

Further, semiconductor devices employing a similar configuration to that described above are also known as semiconductor devices in which a semiconductor chip is flip-chip connected to a wiring board. This type of semiconductor device is disclosed, for example, in Japanese Laid-Open Patent Publication No. H11-168122 (Patent Document 3).

### SUMMARY

As the reduction in size and thickness of semiconductor devices progresses, the allowance in designing packages has also been reduced. This increases the effect of mutual difference in physical property values such as coefficient of thermal expansion among a semiconductor chip, a wiring board and a sealing resin constituting a semiconductor device. For example, difference in physical property values between one surface and the other surface of a semiconductor chip may cause warpage (or stress), leading to breakage of the chip or deterioration in characteristics even if the chip is not broken. Thus, there have been increased problems of deterioration in reliability. In addition, there have been increased problems of deterioration in external packageability caused by warpage in an entire package.

The semiconductor device disclosed in Patent Document 1 is capable of reducing the warpage in a substrate before molding, more particularly, during the mounting of a semiconductor chip on the substrate, but no consideration is given to warpage in a semiconductor chip or in an entire package which may occur after molding. Therefore, this semiconductor device still has problems of deterioration in reliability and poor external packageability.

The semiconductor device described in Patent Document 2 is capable of improving the adhesion between the sealing resin and the semiconductor chip by reducing the bonding area of the adhesive and is capable of enabling the electrode arrangement to be changed to realize size reduction. However, no consideration at all is given, in this semiconductor device, to warpage in the semiconductor chip or in the entire package.

The semiconductor device described in Patent Document 3 is capable of enhancing the connection strength between the wiring board and the semiconductor chip flip-chip connected thereto, by providing an insulation adhesive between the semiconductor chip and the wiring board. However, no consideration is given, in this semiconductor device, to warpage in the semiconductor chip or in the entire package.

In one embodiment, there is provided a device which includes a semiconductor chip, a wiring board, a support which supports the semiconductor chip on the wiring board and which form a gap between the semiconductor chip and the wiring board, and a sealing resin which is injected into the gap and which covers the semiconductor chip.

According to this invention, a support is provided on a wiring board for supporting a semiconductor chip and for forming a gap between the semiconductor chip and the wiring board, whereby a sealing resin can be arranged in a similar manner on both of the opposite surfaces of the semiconductor chip. This makes it possible to substantially equalize the physical property values between the opposite surfaces of the semiconductor chip, and thus to prevent the warpage of the semiconductor chip.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a cross-sectional configuration diagram showing a semiconductor device according to a first embodiment of the invention;

FIG. 2 is a plan transparent view of the semiconductor device shown in FIG. 1;

FIGS. 3A to 3E are process drawings for explaining a method of manufacturing the semiconductor device shown in FIG. 1;

FIG. 4 is a plan transparent view of a semiconductor device according to a second embodiment of the invention;

FIG. 5 is a plan transparent view of a semiconductor device according to a third embodiment of the invention;

FIG. 6 is a cross-sectional configuration diagram showing a semiconductor device according to a fourth embodiment of the invention; and

FIG. 7 is a cross-sectional configuration diagram showing a semiconductor device according to a fifth embodiment of the invention.

### DETAILED DESCRIPTION OF THE EXEMPLARY EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

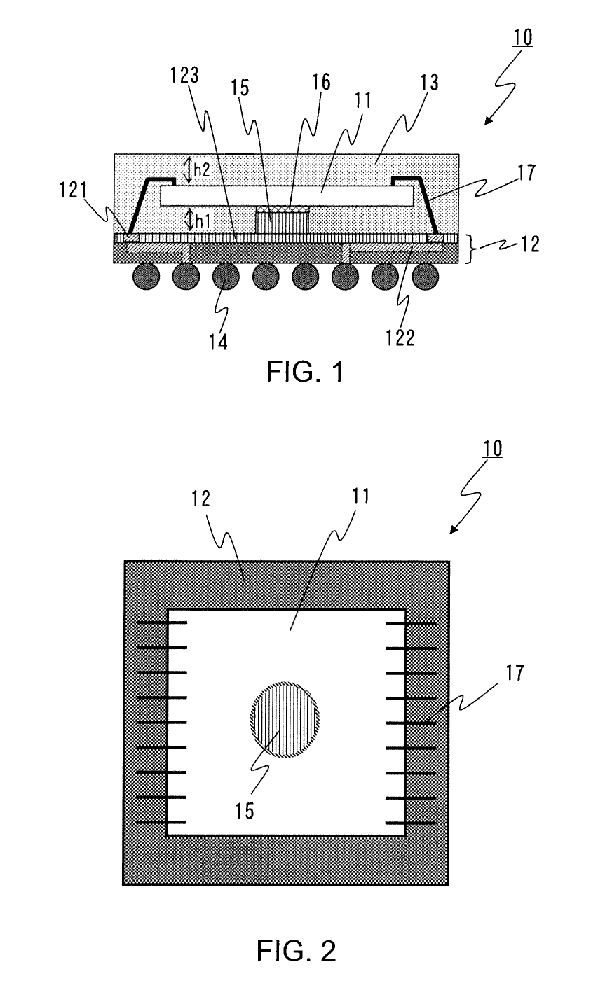

FIG. 1 shows a configuration in cross section of a semiconductor device 10 according to a first embodiment of this invention, and FIG. 2 is a plan transparent view thereof.

As seen from FIG. 1, this semiconductor device 10 is a BGA (Ball Grid Array) type semiconductor device. The semiconductor device 10 has a semiconductor chip 11, a wiring board 12 on which the semiconductor chip 11 is mounted, and a sealing resin 13 sealing the semiconductor chip 11 on the wiring board 12.

The wiring board 12 is, for example, a glass epoxy board having external dimensions slightly greater than those of the semiconductor chip 11. There are formed, on one surface (upper surface) of the wiring board 12, a plurality of connection pads 121 made for example of gold (Au) or copper (Cu), and predetermined wirings 122 connected to the connection pads 121. A solder resist (insulation film) 123 is formed to cover the wirings 122. The solder resist 123 serves to prevent removal of the wiring 122 as well as to avoid adverse effects caused by poor adhesion of the sealing resin 13 to a metal.

There are formed, on the other surface (lower surface) of the wiring board 12, a plurality of lands (not shown) electrically connected to the wirings 122 via through-holes or the like. A solder ball 14 used as an external mounting terminal is mounted on each of these lands.

There is further provided, on the one surface of the wiring board 12, a projection 15 having a flat upper end as a support. This projection 15 is provided in a part of a semiconductor chip mounting region (region facing the semiconductor chip) which corresponds, in this example, to a central part (a position supporting the center of gravity of the semiconductor chip). The percentage of area occupied by the projection in the semiconductor chip mounting region should be as small as possible. Specifically, the area 51 of the surface (upper end surface) of the projection 15 facing the semiconductor chip 11 should 20% or less of the area S2 of the surface (lower surface) of the semiconductor chip 11 facing the projection 15 (S1≦0.2×S2). The shape of the projection 15 may be either circular cylindrical or elliptical cylindrical in consideration of flow of the sealing resin 13 when it is injected. In other words, a circular (elliptical) cylindrical member can be used as the support. This makes it possible to uniformize the fluidity of the resin during a molding process, and to prevent occurrence of void defects in the periphery of the projection 15. The height of the projection 15 is determined according to a thickness of the sealing resin 13. Specifically, the height of the projection 15 is determined such that the distance h1 between the lower surface of the semiconductor chip 11 and the upper surface of the wiring board is equal to the thickness h2 of the sealing resin 13 on the semiconductor chip 11. This makes it possible to equalize the resin amount and the thermal stress caused by heating and cooling processes between the one surface (upper surface) and the other surface (lower surface) of the semiconductor chip 11, and to prevent occurrence of warpage in the semiconductor chip 11. The projection 15 may be formed, for example, of the same material as that of the solder resist 123. By forming the projection 15 of the same material as that of the solder resist 123, good adhesion with the sealing resin 13 can be ensured.

The semiconductor chip 11 is fixed, at its central part of the lower surface, to the upper surface (flat surface) of the projection 15 with the use of an adhesive 16 such as a DAF (Die Attach Film). Since the projection 15 is previously provided on the wiring board 12, the working efficiency of the chip mounting process is not adversely affected. Further, there are formed, on the upper surface of the semiconductor chip 11, a plurality of electrode pads (not shown), which are connected to corresponding connection pads 121 on the wiring board 12 by means of conductive bonding wires 17 of Au or Cu, for example.

The sealing resin 13 is for example an epoxy resin provided on the wiring board 12 so as to cover the entire of the semiconductor chip 11 and the surrounding area of the bonding wires 17. This means that the sealing resin 13 is not only formed to cover the upper surface of the semiconductor chip 11 but also formed between the lower surface of the semiconductor chip 11 and the wiring board 12.

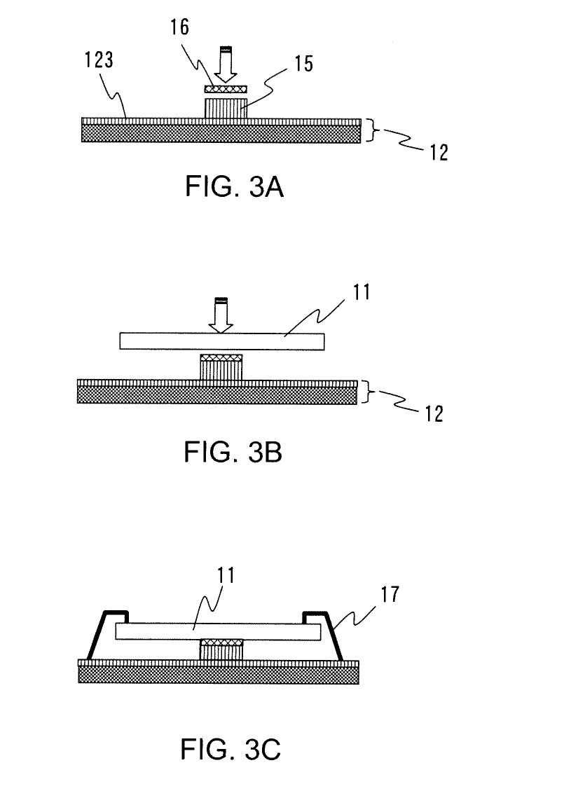

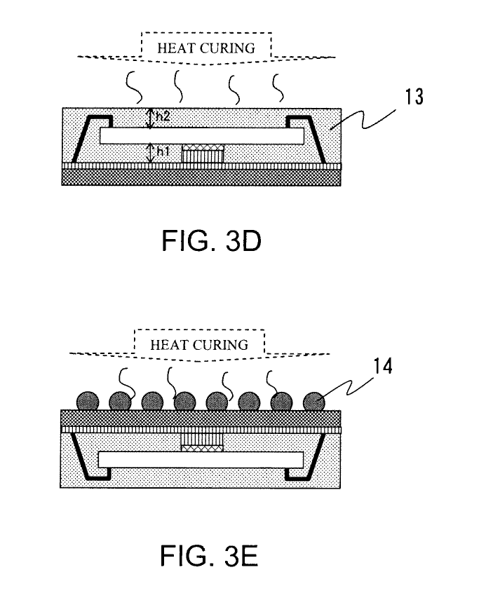

Referring to FIGS. 3A to 3E, a method of manufacturing the semiconductor device according to the first embodiment will be described. Although a method mainly used to manufacture BGA-type semiconductor devices is a MAP (Mold Array Package) method in which a plurality of semiconductor devices are manufactured collectively using a single large-sized wiring board, the following description will be made on an example in which a single semiconductor device is manufactured.

In the first step, a wiring board 12 is prepared, having a circular cylindrical projection 15 made of the same material as that of the solder resist 123 and formed in a central part of its chip mounting region. The height of the projection 15 is slightly smaller (by the thickness of the adhesive 16) than the distance h1 between the lower surface of the semiconductor chip 11 and the upper surface of the wiring board 12. The area of the upper surface of the projection 15 is set to S1 (20% or less of the chip mounting area S2). The formation of the projection 15 may be performed at the same time with formation of the solder resist 123. In this case, etching or laser processing may be employed. Alternatively, the projection 15 may be formed after formation of the solder resist 123. In this case, a two-stage application method or the like may be employed. Still alternatively, the projection 15 may be formed in a separate place and attached to the solder resist 123. The projection 15 can be formed not only by the aforementioned methods but also various other methods.

In the next step, as shown in FIG. 3A, the prepared wiring board 12 is placed with its chip mounting surface facing upward, and a DAF as an adhesive 16 is attached to the upper surface of the projection 15. Although the DAF is more expensive than a liquid adhesive, the costs can be reduced since the attaching area is as small as 20% or less of the area S2 of the lower surface of the semiconductor chip 11. Alternatively, a liquid adhesive instead of the DAF may be used. The liquid adhesive may be dropped onto the projection 15 to form a dome.

In the next step, chip mounting equipment (not shown) is used to position the semiconductor chip 11 such that the central part of the lower surface of the semiconductor chip 11 is located directly above the adhesive 16. Subsequently, as shown in FIG. 3B, the central part of the semiconductor chip 11 is pressed down from above, so that the semiconductor chip 11 is bonded and fixed onto the projection 15 by means of the adhesive 16. A gap having a distance h1 is formed between the peripheral region of the lower surface of the semiconductor chip 11 and the upper surface of the wiring board 12.

In the next step, as shown in FIG. 3C, the electrode pads formed on the upper surface of the semiconductor chip 11 are respectively connected to the corresponding connection pads formed on the upper surface of the wiring board 12 by means of conductive bonding wires 17 by using a wire bonder (not shown).

In the next step, the sealing resin 13 is injected onto the upper side and lower side of the semiconductor chip 11 by using a molding device (not shown). Subsequently, as shown in FIG. 3D, the sealing resin 13 is cured (the sealing resin 13 is fixed by heating, for example, to 180° C. and then cooling the same). The semiconductor chip 11 is covered with the same sealing resin 13 both on its upper and lower sides, and the upper side resin 13 has a thickness h2 that is the same as the thickness h1 of the lower side resin 13. This makes it possible, in this process, to prevent occurrence of thermal stress in the peripheral part of the semiconductor chip 11 during heating and cooling thereof, and to reduce the stress applied to the semiconductor chip 11.

In the next step, as shown in FIG. 3E, the wiring board 12 is turned upside down, and solder balls 14 are mounted at predetermined positions by using a ball mounting device (not shown), and then are reflown (the solder balls are fixed by heating, for example, to 245° C. and cooling the same). In this process as well, it is possible to prevent occurrence of thermal stress in the periphery of the semiconductor chip 11 during heating and cooling thereof, and to reduce the stress applied to the semiconductor chip 11, for the same reason as in the curing process.

Subsequently to this process, a mark formation process and a cutting and dicing process are performed in the same manner as in the manufacturing method of common BGA-type semiconductor devices. The manufacture of the semiconductor device 10 (finished product) is thus completed.

According to this first embodiment of the invention as described above, the formation of the projection 15 on the wiring board 12 as a support facilitates the adjustment of the distance (gap) between the semiconductor chip 11 and the wiring board. This makes it possible to substantially equalize the thickness of the sealing resin 13 located on the upper and lower sides of the semiconductor chip 11, and hence to substantially equalize the physical property value in the upper and lower sides of the semiconductor chip 11. As a result, the occurrence of thermal stress in the periphery of the semiconductor chip 11 and occurrence of stress applied to the semiconductor chip 11 can be reduced, whereby the warpage of the semiconductor chip 11 can be prevented. Additionally, deterioration in electrical characteristics or occurrence of failures due to warpage of the semiconductor chip 11 can be prevented and thus the reliability of a finished product can be improved.

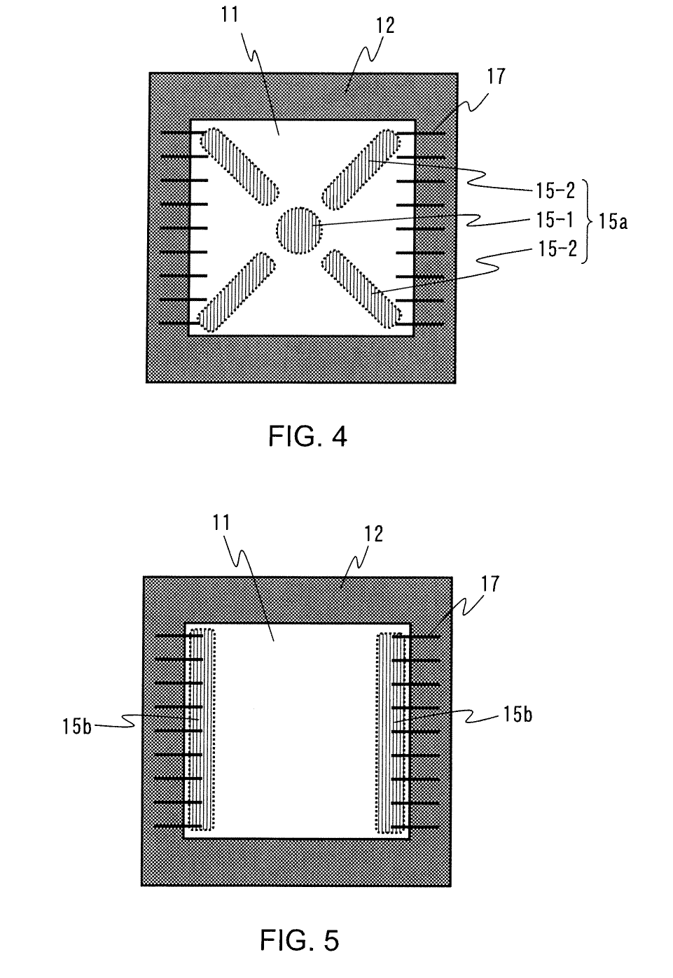

Next, referring to FIG. 4, a semiconductor device according to a second embodiment of this invention will be described.

FIG. 4 is a plan transparent view as seen from above the semiconductor device according to this second embodiment. The shown semiconductor device has the same configuration as that of the semiconductor device according to the first embodiment except that the semiconductor device according to the second embodiment has projections 15a as a support instead of the projection 15 in the semiconductor device according to the first embodiment. Therefore, description of the configuration will be omitted.

The projections 15a include a first projection 15-1 which is a circular cylindrical member provided in a central part of a semiconductor chip mounting region, and second projections 15-2 consisting of four rectangular parallelepiped members (members with a substantially rectangular cross section) extending radially from the central part to four corners. Each corner of the second projections 15-2 may be rounded. The first projection 15-1 is thinner (the upper surface has smaller area) than the projection 15 in the first embodiment. The total sum of the areas of the upper surfaces of the first projection 15-1 and second projections 15-2 is set to 20% or less of the area of the lower surface of the semiconductor chip 11. The second projections 15-2 alone may be provided without providing the first projection 15-1.

According to this second embodiment, the semiconductor chip 11 is secured widely in an “X” fashion from its central part toward four corners. This enables a stable wire bonding work even if the semiconductor chip 11 employs a layout in which electrode pads are arranged in the outer periphery of the chip, whereby bonding failures and breakage of the chip can be reduced. In addition, since the distance between the wiring board 12 and the lower side of the semiconductor chip 11 can be made uniform over the whole area, tremor of the semiconductor chip 11 caused by injection of the resin 13 can be prevented, and hence the occurrence of breakage of the chip or wire cutting failure during resin molding can be reduced.

Next, referring to FIG. 5, a semiconductor device according to a third embodiment of this invention will be described.

FIG. 5 is a plan transparent view of the semiconductor device according to this embodiment as seen from the above. The shown semiconductor device has a pair of projections 15b in place of the projection 15 in the semiconductor device according to the first embodiment. Except for the projections 15b, the semiconductor device according to the third embodiment has the same configuration as that of the semiconductor device according to the first embodiment, and hence description thereof will be omitted.

As shown in FIG. 5, the pair of projections 15b are rectangular parallelepiped members arranged along two parallel sides of the semiconductor chip. Each corner of the projections 15b may be rounded.

According to this embodiment, the semiconductor chip 11 is fixed stably along the two parallel sides in the outer periphery of the chip. This enables a stable wire bonding process when the semiconductor chip 11 employs a layout in which electrode pads are arranged along two parallel sides of the chip. Further, the inflow of the resin can be stabilized and occurrence of void defects can be reduced during the molding process by setting the orientation of the wiring board 12 so that the inflow direction of the resin is parallel with the direction along which the projections 15b extend.

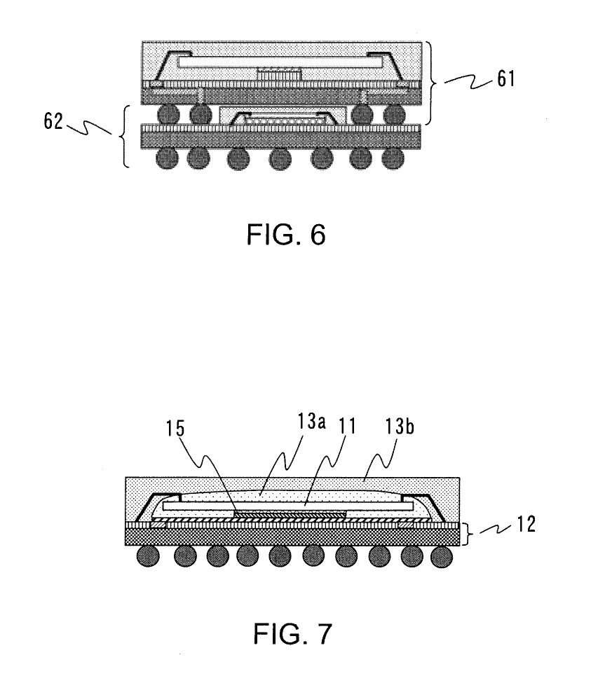

Next, a semiconductor device according to a fourth embodiment of this invention will be described with reference to FIG. 6.

The semiconductor device shown in FIG. 6 is a semiconductor device employing a PoP (Package-on-Package) configuration. This semiconductor device has an upper semiconductor package 61 stacked on a lower semiconductor package 62. The upper semiconductor package 61 employs the same configuration as that of the semiconductor device according to the first embodiment described above.

According to this fourth embodiment, the employment of this configuration makes it possible to minimize the warpage in the packages not only during manufacture of the semiconductor device but also after completion of a finished product, and thus the external packageability can be improved.

The semiconductor packages stacked in a PoP semiconductor device may be either of the same type or of different types. Further, the number of stacked packages may be three or more. Therefore, PoP semiconductor devices are easy to deploy a variety of products and demands for this type of devices have been increased. With the increase of the demands, warpage in each of the stacked packages is required to be minimized. By using a semiconductor device according to any of the first to third embodiments described above as at least one of the semiconductor packages included in a PoP semiconductor device, the warpage of the package can be minimized not only during the manufacturing process of the PoP semiconductor device but also after completion of a finished product, and thus the external packageability can be improved.

Next, a semiconductor device according to a fifth embodiment of this invention will be described with reference to FIG. 7.

The semiconductor device shown in FIG. 7 is different from the semiconductor device according to the first embodiment in terms of having a first sealing resin 13a and a second sealing resin 13b.

The first sealing resin 13a has a lower modulus of elasticity (Young's modulus) than the second sealing resin 13b, for example a modulus of elasticity of about 0.1 GPa. A chip-coating silicon rubber resin (junction coating resin) for example may be used as the first sealing resin 13a.

The second sealing resin 13b has a higher modulus of elasticity than the first sealing resin 13a, for example a modulus of elasticity of about 15 GPa. An epoxy resin for example may be used as the second sealing resin 13b.

The first sealing resin 13a is formed such that the thickness of the resin on the lower side of the semiconductor chip 11 is substantially equal to the thickness of the resin on the upper side of the semiconductor chip 11. The second sealing resin 13b is formed to cover the first sealing resin 13a. Thus, the semiconductor chip 11 is surrounded by the first sealing resin 13a on its upper and lower sides, and the first sealing resin 13a is sealed within the second sealing resin 13b.

According to this embodiment, the semiconductor chip 11 is surrounded by the first sealing resin 13a with a low modulus of elasticity. Therefore, the projection 15 is formed to have a smaller height and a greater upper surface area in comparison with those in the first embodiment (provided that S1≦0.2×S2).

Since the semiconductor chip 11 is surrounded, both on its lower and upper sides, by the first sealing resin 13a, the thermal stress occurring in the periphery the semiconductor chip 11 becomes equal between the upper and lower sides (between the one surface side and the other surface side) of the semiconductor chip 11 in the same manner as in the first embodiment, which prevents occurrence of warpage in the semiconductor chip. Even if warpage occurs in the semiconductor chip 11, the stress is absorbed by the first sealing resin 13a surrounding the semiconductor chip 11. This makes it possible to prevent occurrence of failures such as breakage of the chip caused by the semiconductor chip 11 being inhibited from deformation by the wiring board 12 and the second sealing resin 13b.

Although the invention has been described in conjunction with a few preferred embodiments thereof, the invention is not limited to these embodiments but may be modified in various other manners without departing from the scope and spirit of the invention. For example, the number, shape, and arrangement of the members (projections) constituting the support are not limited to those in the foregoing embodiments but may be changed. For example, the shape may be a rectangular columnar shape. A single rectangular parallelepiped member may be arranged along a center line of the semiconductor chip. Further, this invention is applicable not only to a BGA-type CSP but also to other types of CSP such as a LGA (Land Grid Array)-type CSP.

What is claimed is:

1. A device comprising:
a semiconductor chip;
a wiring board;
a support supporting the semiconductor chip on the wiring board, and forming a gap between the semiconductor chip and the wiring board; and
a sealing resin injected into the gap and covering the semiconductor chip.

2. The device according to claim 1, wherein the thickness of a part of the sealing resin located on one surface of the semiconductor chip is substantially equal to the thickness of a part of the sealing resin located on the other surface of the semiconductor chip.

3. The device according to claim 2, further comprising an adhesive fixing the semiconductor chip to the support, wherein the thickness of the part of the sealing resin located on the one surface of the semiconductor chip is greater than the thickness of the adhesive.

4. The device according to claim 1, wherein the area of the surface of the support facing the semiconductor chip is 20% or less of the area of the surface of the semiconductor chip facing the support.

5. The device according to claim 4, wherein the support comprises a circular cylindrical member.

6. The device according to claim 4, wherein the support comprises a rectangular parallelepiped member.

7. The device according to claim 4, wherein the support comprises a plurality of rectangular parallelepiped members.

8. The device according to claim 7, wherein the plurality of rectangular parallelepiped members are arranged to extend in radial directions.

9. The device according to claim 8, wherein the support further comprises a circular cylindrical member, and the plurality of rectangular parallelepiped members are arranged radially around the circular cylindrical member.

10. The device according to claim 7, wherein the plurality of rectangular parallelepiped members are arranged in parallel with each other.

11. The device according to claim 10, wherein the plurality of rectangular parallelepiped members are arranged along a pair of sides of the semiconductor chip.

12. The device according to claim 1, wherein the wiring board has an insulation film on its surface, and the support is made of the same material as that of the insulation film.

13. The device according to claim 1, wherein the sealing resin has a first modulus of elasticity, and is covered with another sealing resin having a second modulus of elasticity that is higher than the first modulus of elasticity.

14. A semiconductor device comprising:
a wiring board including an upper surface, a lower surface opposite to the upper surface, a connection pad formed on the upper surface;
a semiconductor chip including a first surface, a second surface opposite to the first surface, an electrode pad formed on the first surface, the semiconductor chip being mounted at the second surface thereof over the wiring board;
a supporting member intervening between the second surface of the semiconductor chip and the wiring board, the supporting member being smaller in size than the semiconductor chip;
a conductive wire electrically connected with the electrode pad of the semiconductor chip to the connection pad of the wiring board; and
a sealing resin formed to cover the upper surface of the wiring board, the semiconductor chip, the supporting member, and the conductive wire.

15. The semiconductor device according to claim 14, wherein a thickness of a part of the sealing resin located on the first surface of the semiconductor chip is substantially equal to a thickness of a part of the sealing resin located on the second surface of the semiconductor chip.

16. The semiconductor device according to claim 14, wherein the supporting member is arranged at an area of the second surface corresponding to the electrode pad of the semiconductor chip.

17. The semiconductor device according to claim 14, wherein a size of the supporting member is smaller than 20% or less of a size of the semiconductor chip.

18. The semiconductor device according to claim 14, further comprising:
an external terminal formed on the lower surface of the wiring board.

19. The semiconductor device according to claim 14, wherein the supporting member comprises a shape of a circular cylindrical.
